(19) United States
(12) Patent Application Publication
(10) Pub. No.: US 2023/0079382 A1
(43) Pub. Date: Mar. 16, 2023

(54) Driving Backplane, Method for Manufacturing Same and Display Device

(71) Applicant: BOE Technology Group Co., Ltd., Beijing (CN)

(72) Inventors: Feng GUAN, Beijing (CN); Guangcai YUAN, Beijing (CN); Xue DONG, Beijing (CN); Ce NING, Beijing (CN)

(21) Appl. No.: 17/612,225

(22) PCT Filed: Feb. 1, 2021
(86) PCT No.: PCT/CN2021/074627

§ 371 Date: Nov. 18, 2021

(51) Int. Cl. H01L 27/12

(52) U.S. Cl. CPC H01L 27/124; H01L 27/1259

(57) ABSTRACT

Provided are a driving backplane, a method for manufacturing the same and a display device. The driving backplane includes a substrate, a first gate disposed on a side of the substrate, an active layer disposed on a side of the first gate away from the substrate, and a second gate disposed on a side of the active layer away from the substrate. An orthographic projection of the second gate on the substrate is located in an orthographic projection of the first gate on the substrate, and in a direction parallel to the substrate, an edge of an orthographic projection of the first gate on the substrate extends beyond an edge of the orthographic projection of the second gate on the substrate.

### CROSS-REFERENCE TO RELATED APPLICATION

The present application is a U.S. National Phase Entry of International Application No. PCT/CN2021/074627 having an international filing date of Feb. 1, 2021, the content of which is hereby incorporated by reference.

### TECHNICAL FIELD

The present disclosure relates to, but is not limited to, the field of display technology, in particular to a driving backplane, a method for manufacturing the same and a display device.

### BACKGROUND

Micro LED (Micro Light Emitting Diode) is a new generation of display technology, which has higher brightness, better luminous efficiency and lower power consumption than the existing OLED technology. The aging speed of organic materials used in the existing OLED display devices is faster than that of inorganic materials used in LCD display devices, and OLED display devices will leave residual images when displaying a static picture for a long time, that is, the screen burning phenomenon of OLED display devices will occur. Micro LEDs adopt inorganic light-emitting materials, which have higher stability and service life.

Micro LED is pixel level self-luminous. It miniaturizes the traditional inorganic LED array. Each LED pixel point with a size of several microns can be independently addressed and lit. Therefore, micro LED has more advantages than the existing OLED technology.

Micro LED is a current type device, and the luminous accuracy is particularly sensitive to the stability of current. Therefore, higher requirements are put forward for the existing LTPS (Low Temperature Polycrystalline Silicon) technology.

### SUMMARY

The following is a brief description of the subject matter detailed herein. This brief description is not intended to limit the scope of protection of the claims.

A driving backplane includes a substrate, a first gate disposed on one side of the substrate, an active layer disposed on a side of the first gate away from the substrate, and a second gate disposed on a side of the active layer away from the substrate, wherein an orthographic projection of the second gate on the substrate is located in an orthographic projection of the first gate on the substrate, and in a direction parallel to the substrate, an edge of the orthographic projection of the first gate on the substrate extends beyond an edge of the orthographic projection of the second gate on the substrate.

In an exemplary embodiment, the driving backplane further includes a gate insulating layer disposed on the side of the active layer away from the substrate, and a first via exposing at least part of a region of the first gate is disposed in the gate insulating layer; and/or, the driving backplane further includes an interlayer dielectric layer disposed on the side of the second gate away from the substrate, and a second via exposing at least part of the region of the first gate and a third via exposing at least part of a region of the second gate are disposed in the interlayer dielectric layer.

In an exemplary embodiment, the first via exposing at least part of the region of the first gate is disposed in the gate insulating layer and the second gate is connected with the first gate through the first via.

In an exemplary embodiment, the distance between an edge of the side of the first via close to the active layer and an edge of the side of the active layer close to the first via is greater than or equal to a process tolerance.

In an exemplary embodiment, the distance between the edge of the side of the first via close to the active layer and the edge of the side of the active layer close to the first via is greater than or equal to 1.5 um.

In an exemplary embodiment, the second via exposing at least part of the region of the first gate and the third via exposing at least part of the region of the second gate are disposed in the interlayer dielectric layer, the driving backplane further includes a first source drain layer disposed on the side of the interlayer dielectric layer away from the substrate, and the first source drain layer is bridged with the first gate and the second gate respectively through the second via and the third via.

In an exemplary embodiment, the first via exposing at least part of the region of the first gate is disposed in the gate insulating layer; the second via exposing at least part of the region of the first gate and the third via exposing at least part of the region of the second gate are disposed in the interlayer dielectric layer, the second gate is connected with the first gate through the first via, the driving backplane further includes a first source drain layer disposed on the side of the interlayer dielectric layer away from the substrate, and the first source drain layer is bridged with the first gate and the second gate respectively through the second via and the third via.

In an exemplary embodiment, the distance between the edge of the orthographic projection of the first gate on the substrate and the edge of the orthographic projection of the second gate on the substrate is 0.5 um-5 um.

In an exemplary embodiment, a fourth via exposing at least part of the region of the active layer is disposed in the interlayer dielectric layer, the driving backplane further includes a first source drain layer disposed on the side of the interlayer dielectric layer away from the substrate, and the first source drain layer is connected with the active layer through the fourth via.

In an exemplary embodiment, a material of the first source drain layer is copper, and a seed layer is disposed between the first source drain layer and the active layer.

In an exemplary embodiment, a back circuit layer is disposed on a side of the substrate away from the first gate, a bonding electrode is disposed on a side of the substrate away from the back circuit layer, and the bonding electrode is connected with the back circuit layer.

In an exemplary embodiment, the back circuit layer includes a wire layer disposed on the side of the substrate away from the first gate and a connecting electrode disposed on the side of the wire layer away from the substrate, and the bonding electrode is connected with the connecting electrode through the wire layer.

A display device, including the driving backplane described above.

A method for manufacturing a driving backplane, includes:

forming a first gate on one side of a substrate;

forming an active layer on a side of the first gate away from the substrate;

forming a gate insulating layer on a side of the active layer away from the substrate;

forming a second gate on a side of the gate insulating layer away from the substrate;

forming an interlayer dielectric layer on a side of the second gate away from the substrate,

forming a first source drain layer on a side of the interlayer dielectric layer away from the substrate, wherein

an orthographic projection of the second gate on the substrate is located in an orthographic projection of the first gate on the substrate, and in a direction parallel to the substrate, an edge of the orthographic projection of the first gate on the substrate extends beyond an edge of the orthographic projection of the second gate on the substrate.

After reading and understanding the drawings and the detailed description, other aspects can be understood.

### BRIEF DESCRIPTION OF DRAWINGS

The drawings are used to provide a further understanding of the technical solution of the present disclosure, constitute a part of the specification, are used together with the embodiments of the present disclosure to explain the technical solution of the present disclosure, and do not constitute limitations to the technical solution of the present disclosure. The shape and size of each component in the drawings do not reflect the actual scale, and the purpose is only to schematically illustrate the contents of the present disclosure.

FIG. 1 illustrates a top view of a driving backplane according to an exemplary embodiment of the present disclosure.

FIG. 2 illustrates a sectional view 1 of A-A′ in FIG. 1.

FIG. 3 illustrates a sectional view 2 of A-A′ in FIG. 1.

FIG. 4 illustrates a sectional view of B-B′ in FIG. 1.

FIG. 5 illustrates a sectional view of a back circuit layer according to an exemplary embodiment of the present disclosure.

### DETAILED DESCRIPTION

The embodiments herein may be implemented in a plurality of different forms. Those skilled in the art can easily understand the fact that the embodiments and content may be transformed into various forms without departing from the purpose and scope of the present disclosure. Therefore, the present disclosure should not be interpreted as limited to the content recorded in the following embodiments. Without conflict, the embodiments in the present disclosure and the features in the embodiments may be freely combined with each other.

In the drawings, sometimes the size of the constituent elements, the thickness or region of the layer may be exaggerated for the sake of clarity. Therefore, any implementation of the present disclosure is not necessarily limited to the size illustrated in the drawing, and the shape and size of the components in the drawing do not reflect the actual scale. In addition, the drawings schematically illustrate ideal examples, and any implementation of the present disclosure is not limited to the shape or value illustrated in the drawings.

The ordinal numerals “first”, “second” and “third” herein are set up to avoid the confusion of the constituent elements, not to limit the quantity.

Herein, for the sake of convenience, “middle”, “up”, “down”, “front”, “back”, “vertical”, “horizontal”, “top”, “bottom”, “inside”, “outside” and other words indicating an orientation or positional relationship are used to describe the positional relationship of constituent elements with reference to the drawings, only for the convenience of describing the embodiments and simplifying the description, rather than indicating or implying that the device or element must have a specific orientation or be constructed and operated in a specific orientation, so they should not be understood as limitations to the present disclosure. The positional relationship of the constituent elements may be appropriately changed according to the direction of the described constituent elements. Therefore, it is not limited to the words and sentences described herein, and can be changed appropriately according to the situation.

Herein, unless otherwise specified and limited, the terms “mount”, “connected” and “connect” shall be understood in a broad sense. For example, it may be fixed connection, removable connection, or integrated connection; it may be mechanical connection or electrical connection; it may be direct connection, indirect connection through an intermediate component, or communication inside two components. For those skilled in the art, the meaning of the above terms in the present disclosure may be understood according to the situation.

Herein, “parallel” refers to a state in which an angle formed by two straight lines is more than −10° and less than 10°. Therefore, it also includes a state in which an angle is more than −5° and less than 5°. In addition, “vertical” refers to a state in which an angle formed by two straight lines is more than 80° and less than 100°. Therefore, it also includes a state in which an angle is more than 85° and less than 95°.

Herein, “approximate” refers to a numerical value within an allowable process and measurement error range without strictly limiting the limits.

A single-gate transistor has only one gate, this gate may be located on the side of an active layer away from a substrate or on the side of the active layer close to the substrate. A double-gate transistor has gates on two sides of the active layer, and a channel region is sandwiched between the two gates. Through the research of the inventor, it is found that under a condition that the channel region has the same width (W)-length (L) ratio, the saturation current of the double-gate transistor is greater than that of the single-gate transistor. Exemplarily, a driving transistor in the present disclosure is a double-gate transistor.

In the related art, a driving backplane includes a first gate and a second gate which are disposed opposite, and an active layer disposed between the first gate and the second gate. A process of manufacturing the driving backplane includes: firstly forming a first gate, then forming an active layer on the first gate, and finally forming a second gate on the active layer. When the channel region of the active layer is manufactured, firstly a layer of amorphous silicon film is deposited, and then the amorphous silicon film is crystallized through processes such as dehydrogenation and Excimer Laser Annealing (ELA) to form the channel region of the active layer. Since the edge of the first gate has a slope, a buffer layer on the first gate is uneven at the edge of the first gate, the channel region of the active layer has a segment difference at the edge of the first gate. Further, in the crystallization process, there is a laser focal plane difference in the thin amorphous silicon film at the edge of the first gate, resulting in poor crystallization quality of the amorphous silicon film, and affecting the performance of the active layer.

The present disclosure provides a driving backplane, which includes a substrate, a first gate disposed on one side of the substrate, an active layer disposed on a side of the first gate away from the substrate, and a second gate disposed on a side of the active layer away from the substrate. An orthographic projection of the second gate on the substrate is located in an orthographic projection of the first gate on the substrate, and in a direction parallel to the substrate, an edge of the orthographic projection of the first gate on the substrate extends beyond an edge of the orthographic projection of the second gate on the substrate.

In the driving backplane provided by the embodiment of the present invention, the edge of the orthographic projection of the first gate on the substrate is extended beyond the edge of the orthographic projection of the second gate on the substrate, so that the active layer is prevented from forming a segment difference at the edge of the first gate in the crystallization process of the active layer, thus ensuring the crystallization quality of the active layer.

Next, the structure, principle and effect of an array substrate provided by the present disclosure will be further explained and described below with reference to the drawings.

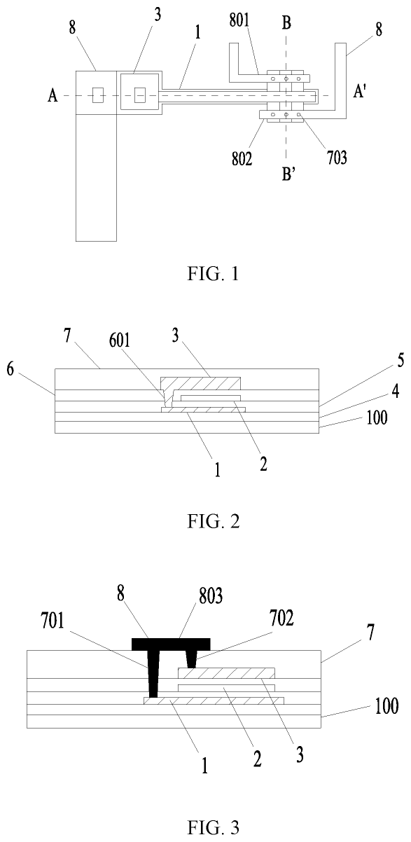

FIG. 1 illustrates a top view of a driving backplane according to an exemplary embodiment of the present disclosure. FIG. 2 illustrates a sectional view 1 of A-A′ in FIG. 1. Referring to FIG. 1 and FIG. 2, the driving backplane includes a substrate 100, a first buffer layer 4 disposed on one side of the substrate 100, a first gate 1 disposed on the first buffer layer 4 away from the substrate 100, a second buffer layer 5 disposed on a side of the first gate 1 away from the substrate 100, an active layer 2 disposed on a side of the second buffer layer 5 away from the substrate 100, a gate insulating layer 6 disposed on a side of the active layer 2 away from the substrate 100, a second gate 3 disposed on a side of the gate insulating layer 6 away from the substrate 100, and an interlayer dielectric layer 7 disposed on a side of the second gate 3 away from the substrate 100. An orthographic projection of the second gate 3 on the substrate 100 is located in an orthographic projection of the first gate 1 on the substrate 100, and in a direction parallel to the substrate 100, an edge of the orthographic projection of the first gate 1 on the substrate 100 extends beyond an edge of the orthographic projection of the second gate 3 on the substrate 100.

The substrate 100 may be an inorganic substrate 100 or an organic substrate 100. In an embodiment of the present disclosure, a material of the substrate 100 may be a glass material such as soda lime glass, quartz glass or sapphire glass, or a metal material such as stainless steel, aluminum or nickel. In another embodiment of the present disclosure, the material of the substrate 100 may be polymethylmethacrylate (PMMA), polyvinyl alcohol (PVA), polyvinylphenol (PVP), polyether sulfone (PES), polyimide, polyamide, polyacetal, polycarbonate (PC) polyethylene terephthalate (PET), polyethylene naphthalate (PEN) or a combination thereof. In another embodiment of the present disclosure, the substrate 100 may also be a flexible substrate 100. For example, the material of the substrate 100 may be polyimide (PI). The substrate 100 may also be a composite of multiple layers of materials. For example, in an embodiment of the present disclosure, the substrate 100 may include a bottom film, a pressure-sensitive adhesive layer, a first polyimide layer and a second polyimide layer stacked sequentially.

The first buffer layer 4 may include an inorganic insulating material, such as silicon nitride, silicon oxide or silicon oxynitride. For example, in an embodiment of the present disclosure, the first buffer layer 4 includes a silicon nitride layer and a silicon oxide layer sequentially stacked on the substrate 100. The thickness of the silicon nitride layer is 40-60 nm and the thickness of the silicon oxide layer is 180-220 nm.

The materials of the first gate 1 and the second gate 3 may be selected from conductive materials, such as metals, conductive metal oxides, conductive polymers, conductive composites, or combinations thereof. Exemplarily, the metal may be selected from platinum, gold, silver, aluminum, chromium, nickel, copper, molybdenum, titanium, magnesium, calcium, barium, sodium, palladium, iron, manganese or a combination thereof. Exemplarily, the conductive metal oxide may be selected from indium oxide, tin oxide, indium tin oxide, fluorine doped tin oxide, aluminum doped zinc oxide, gallium doped zinc oxide, or a combination thereof. Exemplarily, the conductive polymer may be selected from polyaniline, polypyrrole, polythiophene, polyacetylene, poly (3,4-ethylenedioxythiophene)/polystyrene sulfonic acid (PEDOT/PSS) or a combination thereof. The conductive polymer may also be added with acid (such as hydrochloric acid, sulfuric acid or sulfonic acid), Lewis acid (such as phosphorus fluoride, arsenic fluoride or ferric chloride), halogen, and other dopants such as alkali metal. For example, the conductive composite material may be selected from a conductive composite material dispersed with carbon black, graphite powder, metal particles, etc.

The first gate 1 and the second gate 3 may be one layer of conductive material or a stack of multiple layers of conductive materials. For example, in an embodiment of the present disclosure, the first gate 1 and the second gate 3 may include a first conductive material layer, a second conductive material layer and a first conductive material layer stacked sequentially, that is, a sandwich structure. The first conductive material layer may be made of corrosion-resistant metal or alloy, for example, molybdenum or titanium; the second conductive material layer may be a metal or alloy with high conductivity, for example, copper, aluminum, silver, etc. For another example, in another embodiment of the present disclosure, the first gate 1 and the second gate 3 may include a layer of conductive material. For example, the materials of the first gate 1 and the second gate 3 may be molybdenum. The thickness of the first gate 1 and the second gate 3 may be 30-300 nm.

Alternatively, a gate material layer may be firstly formed on one side of the substrate 100, and then the gate material layer may be patterned to form a first gate 1 or a second gate. Alternatively, the first gate 1 and the second gate 3 may be formed by magnetron sputtering. In some other embodiments, the first gate 1 and the second gate 3 may be directly formed by screen printing or the like.

In an embodiment of the present disclosure, the second buffer layer 5 may be made of an organic or inorganic insulating material. Alternatively, the material of the second buffer layer 5 may be silicon oxide, silicon nitride, silicon oxynitride or other inorganic insulating materials. For example, in an embodiment of the present disclosure, the material of the second buffer layer 5 may be silicon oxide, and the thickness may be 0.5 um-5 um.

Alternatively, the second buffer layer 5 may be formed by physical vapor deposition, chemical vapor deposition, spin coating, screen printing or other methods, which is not limited in the present disclosure. For example, in an embodiment of the present disclosure, a layer of silica may be deposited on the side of the first gate 1 away from the substrate 100 by Plasma Enhanced Chemical Vapor Deposition (PECVD) to form the second buffer layer 5.

The active layer 2 is disposed on the side of the second buffer layer 5 away from the substrate 100, which may include an amorphous silicon semiconductor material, a low-temperature polycrystalline silicon semiconductor material, a monocrystalline silicon semiconductor material, a metal oxide semiconductor material, an organic semiconductor material or other types of semiconductor materials.

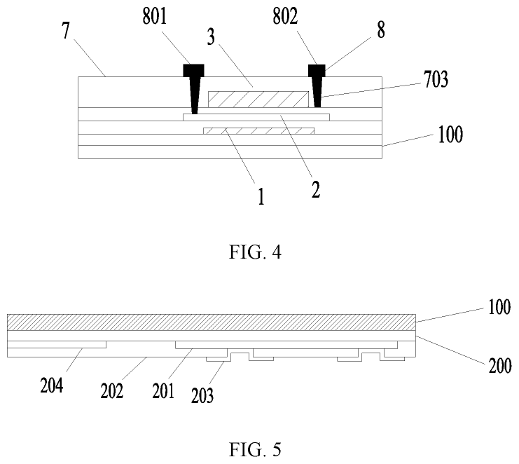

FIG. 4 illustrates a sectional view of B-B′ in FIG. 1. Referring to FIG. 1 and FIG. 4, the driving backplane further includes a first source drain layer 8 disposed on a side of the interlayer dielectric layer 7 away from the substrate 100. A fourth via 703 exposing at least part of the region of the active layer 2 is disposed in the interlayer dielectric layer 7. The active layer 2 may include a channel region, and a source contact region and a drain contact region located on two sides of the channel region. The fourth via 703 exposes the source contact region and the drain contact region, respectively. The first source drain layer 8 includes a source 801 and a drain 802. The source 801 is electrically connected with the source contact region through the fourth via 703, and the drain 802 is electrically connected with the drain contact region through the fourth via 703. The orthographic projection of the channel region on the substrate overlaps with the orthographic projection of the first gate 1 on the substrate and the orthographic projection of the second gate 3 on the substrate 100 respectively, so that the channel region is fully controlled by the first gate 1 and the second gate 3, and the floating body effect of the driving backplane can be eliminated.

Alternatively, the first source drain layer 8 may be formed by magnetron sputtering or electroplating, so that the first source drain layer 8 is connected with the source contact region and drain contact region of the active layer.

In an exemplary embodiment, the material of the first source drain layer 8 is copper, a seed layer is disposed between the first source drain layer 8 and the active layer 2, and the seed layer prevents the copper material of the first source drain layer 8 from diffusing to the active layer 2. Specifically, a seed layer is formed on the active layer 2 firstly by magnetron sputtering, and then a copper first source drain layer 8 is formed on the seed layer by electroplating process. The seed layer may be made of metal titanium or metal molybdenum, which can form good contact with the polysilicon material of the active layer 2 and prevent the diffusion of the copper material. The thickness of the first source drain layer 8 is 1-10 um. Preferably, an anti-diffusion layer may be further disposed between the seed layer and the first source drain layer, and the material of the anti-diffusion layer may be copper alloy. In the present disclosure, the first source drain layer is made of copper, thus effectively reducing the resistance and voltage drop (IR drop) of the driving backplane.

In an exemplary embodiment, the edge of the orthographic projection of the first gate 1 on the substrate 100 extends beyond the edge of the orthographic projection of the channel region on the substrate 100, and the distance between the edge of the orthographic projection of the channel region on the substrate 100 and the edge of the orthographic projection of the first gate 1 on the substrate 100 is 0.5 um-5 um, so that when the amorphous silicon layer is scanned with excimer laser, the amorphous silicon layer is prevented from forming a segment difference at the edge of the first gate 1 which affects the crystallization quality of the channel region.

In an exemplary embodiment, the material of the active layer 2 may include low-temperature polysilicon. Further, the thickness of the active layer 2 is 30-60 nm to avoid reducing the saturation current of the driving backplane due to too small thickness.

In an exemplary embodiment, an amorphous silicon layer is formed on the side of the second buffer layer 5 away from the substrate 100 by plasma enhanced chemical vapor deposition, and then the amorphous silicon layer is scanned with excimer laser to crystallize the amorphous silicon layer into a low-temperature polysilicon layer to form the channel region of the active layer.

Referring to FIG. 1 and FIG. 2, a first via 601 exposing at least part of the region of the first gate 1 is disposed in the gate insulating layer 6, the first via 601 penetrates the gate insulating layer 6 and the second buffer layer 5, and an orthographic projection of the first via 601 on the substrate 100 is located on an orthographic projection of the first gate layer 1 on the substrate 100. The second gate 3 is connected to the first gate 1 through the first via 601. The material and thickness of the gate insulating layer 6 may be the same as or different from that of the second buffer layer 5. In an embodiment of the present disclosure, the gate insulating layer 6 is made of silicon oxide with a thickness of 60-200 nm. The gate insulating layer 6 may be formed by plasma enhanced chemical vapor deposition.

In an embodiment of the present disclosure, the second gate is connected with the first gate through the first via, so that the first gate and the second gate can have the same voltage, which can effectively isolate the active layer and the substrate, avoid the formation of capacitance and charge accumulation between the active layer and the substrate, and then weaken or eliminate the floating body effect of the driving backplane. When the first gate and the second gate are loaded with driving signals related to data voltage, an electric field generated by the first gate and the second gate can act on the channel region of the driving backplane at the same time, so that the channel region can output driving current more effectively and accurately in response to the data voltage. In addition, the first gate and the second gate are electrically connected with each other, thus avoiding the formation of parasitic capacitance between the first gate and the second gate, and avoiding the influence of parasitic capacitance on the driving backplane.

In an exemplary embodiment, the distance between the edge of the side of the first via 601 close to the active layer 2 and the edge of the side of the active layer 2 close to the first via 601 is greater than or equal to a process tolerance, so as to avoid that the first via 601 opens the active layer 2 due to the process tolerance in the process of forming the first via 601, and prevent the electric field formed by the metal electrode connecting the first gate and the second gate in the first via 601 from affecting the carrier distribution in the active layer.

In an exemplary embodiment, the distance between the edge of the side of the first via 601 close to the active layer 2 and the edge of the side of the active layer 2 close to the first via 601 is greater than or equal to 1.5 um. In the process of forming the first via 601 by drilling in the gate insulating layer 6, the process tolerance of the drilling is generally 0.6 um. In the present disclosure, the distance between the edge of the first via 601 and the edge of the active layer 2 is greater than or equal to 1.5 um, which can effectively prevent the first via 601 from opening the active layer 2 due to the process tolerance.

FIG. 3 illustrates a sectional view 2 of A-A′ in FIG. 1. Referring to FIG. 1 and FIG. 3, a second via 701 exposing at least part of the region of the first gate 1 and a third via 702 exposing at least part of the region of the second gate 3 are disposed in the interlayer dielectric layer 7 of the driving backplane in the embodiment of the present disclosure. In other words, when the interlayer dielectric material layer is patterned, the second via and the third via can be formed. The second via penetrates the interlayer dielectric layer 7, the gate insulating layer 6 and the second buffer layer 5. The orthographic projection of the second via on the substrate 100 is located on the orthographic projection of the first gate 1 on the substrate 100. The third via penetrates the interlayer dielectric layer 7, and the orthographic projection of the third via on the substrate 100 is located on the orthographic projection of the second gate 3 on the substrate 100.

The first source drain layer 8 includes a bridging electrode 803, one terminal of the bridging electrode 803 in the first source drain layer 8 is connected with the first gate 1 through the second via 701, and the other terminal of the bridging electrode 803 in the first source drain layer 8 is connected with the second gate 3 through the third via 702, so that the first gate 1 and the second gate 3 are bridged through the first source drain layer 8.

In some embodiments, the first via exposing at least part of the region of the first gate is disposed in the gate insulating layer in the driving backplane, the second via exposing at least part of the region of the first gate and the third via exposing at least part of the region of the second gate are disposed in the interlayer dielectric layer, and the second gate is connected with the first gate through the first via, and the bridging electrode in the first source drain layer is bridged with the first gate and the second gate respectively through the second via and the third via.

In an exemplary embodiment, the interlayer dielectric layer 7 is disposed on the side of the second gate 3 away from the substrate 100 for isolating the second gate 3 and the first source drain layer 8. Alternatively, the material of the interlayer dielectric layer 7 may be an inorganic insulating material.

The interlayer dielectric layer 7 may include one layer of insulating material or multiple layers of laminated insulating material. For example, in an embodiment of the present disclosure, the interlayer dielectric layer 7 may include a silicon nitride layer and a silicon oxide layer successively stacked on the side of the second gate 3 away from the substrate 100, the thickness of the silicon nitride layer is 150-250 nm and the thickness of the silicon oxide layer is 250-350 nm.

Alternatively, an interlayer dielectric material layer may be formed on the side of the second gate 3 away from the substrate 100, and then the interlayer dielectric material layer may be patterned to form an interlayer dielectric layer 7. Preferably, an interlayer dielectric material layer may be formed by plasma enhanced chemical vapor deposition.

FIG. 5 illustrates a sectional view of a back circuit layer according to an exemplary embodiment of the present disclosure. Referring to FIG. 5, a back circuit layer 200 is disposed on the side of the substrate 100 away from the first gate 1, and a signal lead and a bonding electrode connected with the signal lead are disposed on the side of the substrate 100 away from the back circuit layer 200. The bonding electrode is connected with the back circuit layer 200, so as to transfer IC/output ports and the like to the back circuit layer 200, so as to manufacture a frameless display device, so that the display device can be seamlessly spliced to form a large-screen display device. The size of the display device is no longer limited by the size of the manufacturing equipment, and it can be used for self-customized splicing to define any size.

The back circuit layer 200 includes a wire layer 201, a passivation layer 202 and a connecting electrode 203 sequentially disposed on the substrate. A fifth via exposing the wire layer 201 is disposed in the passivation layer 202, and the connecting electrode 203 is connected with the wire layer 201 through the fifth via. The wire layer 201 is connected to the bonding electrode 14 to realize the input of the signal.

In an embodiment of the present disclosure, the back circuit layer 200 further includes an alignment marking layer 204, which is disposed on the same layer as the wire layer 201, and the alignment marking layer 204 is made of a light-permeable material, such as ITO, SiNx or SiOx.

A display device includes the driving backplane described above. The display device provided by the embodiment of the present disclosure be any product or component with a display function, such as mobile phone, tablet computer, TV, display, notebook computer, digital photo frame, navigator, etc.

A method for manufacturing a driving backplane includes:

forming a first gate on one side of a substrate;

forming an active layer on the side of the first gate away from the substrate;

forming a gate insulating layer on the side of the active layer away from the substrate;

forming a second gate on the side of the gate insulating layer away from the substrate;

forming an interlayer dielectric layer on the side of the second gate away from the substrate, wherein

an orthographic projection of the second gate on the substrate is located in an orthographic projection of the first gate on the substrate, and in a direction parallel to the substrate, an edge of the orthographic projection of the first gate on the substrate extends beyond an edge of the orthographic projection of the second gate on the substrate.

Although the embodiments disclosed in the present disclosure are as above, the contents described are only embodiments adopted for the convenience of understanding the present disclosure and are not used to limit the present disclosure. Any person skilled in the art may make any modification and change in the form and details of the implementation without departing from the spirit and scope disclosed in the present disclosure. However, the scope of protection of the present disclosure shall still be subject to the scope defined in the appended claims.

What is claimed is:

1. A driving backplane, comprising a substrate, a first gate disposed on one side of the substrate, an active layer disposed on a side of the first gate away from the substrate, and a second gate disposed on a side of the active layer away from the substrate, wherein an orthographic projection of the second gate on the substrate is located in an orthographic projection of the first gate on the substrate, and in a direction parallel to the substrate, an edge of the orthographic projection of the first gate on the substrate extends beyond an edge of the orthographic projection of the second gate on the substrate.

2. The driving backplane according to claim 1, wherein the driving backplane further comprises a gate insulating layer disposed on the side of the active layer away from the substrate, wherein a first via exposing at least part of a region of the first gate is disposed in the gate insulating layer; and/or, the driving backplane further comprises an interlayer dielectric layer disposed on a side of the second gate away from the substrate, wherein a second via exposing at least part of the region of the first gate and a third via exposing at least part of a region of the second gate are disposed in the interlayer dielectric layer.

3. The driving backplane according to claim 2, wherein the first via exposing at least part of the region of the first gate is disposed in the gate insulating layer, and the second gate is connected with the first gate through the first via.

4. The driving backplane according to claim 3, wherein a distance between an edge of the side of the first via close to the active layer and an edge of the side of the active layer close to the first via is greater than or equal to a process tolerance.

5. The driving backplane according to claim 4, wherein the distance between the edge of the side of the first via close to the active layer and the edge of the side of the active layer close to the first via is greater than or equal to 1.5 um.

6. The driving backplane according to claim 2, wherein the second via exposing at least part of the region of the first gate and the third via exposing at least part of the region of the second gate are disposed in the interlayer dielectric layer, and the driving backplane further comprises a first source drain layer disposed on a side of the interlayer dielectric layer away from the substrate, wherein the first source drain layer is bridged with the first gate and the second gate respectively through the second via and the third via.

7. The driving backplane according to claim 2, wherein the first via exposing at least part of the region of the first gate is disposed in the gate insulating layer; the second via exposing at least part of the region of the first gate and the third via exposing at least part of the region of the second gate are disposed in the interlayer dielectric layer, the second gate is connected with the first gate through the first via, the driving backplane further comprises a first source drain layer disposed on a side of the interlayer dielectric layer away from the substrate, and the first source drain layer is bridged with the first gate and the second gate respectively through the second via and the third via.

8. The driving backplane according to claim 1, wherein a distance between the edge of the orthographic projection of the first gate on the substrate and the edge of the orthographic projection of the second gate on the substrate is 0.5 um-5 um.

9. The driving backplane according to claim 2, wherein a fourth via exposing at least part of a region of the active layer is disposed in the interlayer dielectric layer, the driving backplane further comprises a first source drain layer disposed on a side of the interlayer dielectric layer away from the substrate, wherein the first source drain layer is connected with the active layer through the fourth via.

10. The driving backplane according to claim 9, wherein a material of the first source drain layer is copper, and a seed layer is disposed between the first source drain layer and the active layer.

11. The driving backplane according to claim 1, wherein a back circuit layer is disposed on a side of the substrate away from the first gate, a bonding electrode is disposed on a side of the substrate away from the back circuit layer, and the bonding electrode is connected with the back circuit layer.

12. The driving backplane according to claim 11, wherein the back circuit layer comprises a wire layer disposed on the side of the substrate away from the first gate and a connecting electrode disposed on a side of the wire layer away from the substrate, and the bonding electrode is connected with the connecting electrode through the wire layer.

13. A display device, comprising the driving backplane according to claim 1.

14. A method for manufacturing a driving backplane, comprising:
forming a first gate on a side of a substrate;
forming an active layer on a side of the first gate away from the substrate;
forming a gate insulating layer on a side of the active layer away from the substrate;
forming a second gate on a side of the gate insulating layer away from the substrate;
forming an interlayer dielectric layer on a side of the second gate away from the substrate,
wherein an orthographic projection of the second gate on the substrate is located in an orthographic projection of the first gate on the substrate, and in a direction parallel to the substrate, an edge of the orthographic projection of the first gate on the substrate extends beyond an edge of the orthographic projection of the second gate on the substrate.

15. The driving backplane according to claim 3, wherein a fourth via exposing at least part of a region of the active layer is disposed in the interlayer dielectric layer, the driving backplane further comprises a first source drain layer disposed on a side of the interlayer dielectric layer away from the substrate, wherein the first source drain layer is connected with the active layer through the fourth via.

16. The driving backplane according to claim 6, wherein a fourth via exposing at least part of a region of the active layer is disposed in the interlayer dielectric layer, the driving backplane further comprises a first source drain layer disposed on a side of the interlayer dielectric layer away from the substrate, wherein the first source drain layer is connected with the active layer through the fourth via.

17. The driving backplane according to claim 7, wherein a fourth via exposing at least part of a region of the active layer is disposed in the interlayer dielectric layer, the driving backplane further comprises a first source drain layer disposed on a side of the interlayer dielectric layer away from the substrate, wherein the first source drain layer is connected with the active layer through the fourth via.

18. The driving backplane according to claim 2, wherein a back circuit layer is disposed on a side of the substrate away from the first gate, a bonding electrode is disposed on a side of the substrate away from the back circuit layer, and the bonding electrode is connected with the back circuit layer.

19. The driving backplane according to claim 3, wherein a back circuit layer is disposed on a side of the substrate away from the first gate, a bonding electrode is disposed on a side of the substrate away from the back circuit layer, and the bonding electrode is connected with the back circuit layer.

20. The driving backplane according to claim 6, wherein a back circuit layer is disposed on a side of the substrate away from the first gate, a bonding electrode is disposed on a side of the substrate away from the back circuit layer, and the bonding electrode is connected with the back circuit layer.
